(19) United States
(12) Patent Application Publication
(10) Pub. No.: US 2022/0208421 A1
(43) Pub. Date: Jun. 30, 2022

(54) IDEAL DIAMAGNETIC RESPONSE OF A GRAPHENE-n-HEPTANE-PERMALLOY SYSTEM

(71) Applicant: Chapman University, Orange, CA (US)

(72) Inventors: Armen Gulian, Ashton, MD (US); Rajendra Dulal, Burtonsville, MD (US); Yasushi Kawashima, Tokyo (JP); Serafim Teknowijoyo, Burtonsville, MD (US); Sara Chahid, Laurel, MD (US)

(21) Appl. No.: 17/206,441

(22) Filed: Mar. 19, 2021

Related U.S. Application Data
(60) Provisional application No. 62/992,391, filed on Mar. 20, 2020.

(51) Int. Cl. H01F 1/00; H01F 10/28; H01F 10/30; H01F 10/14; H01F 41/22

(52) U.S. Cl. CPC H01F 1/0018; H01F 10/28; C23C 16/06; H01F 10/14; H01F 41/22; H01F 10/30

(57) ABSTRACT

Systems, methods, and apparatus for generating an ideal diamagnetic response are disclosed. A disclosed diamagnetic system includes a metal foil or a first substrate having at least one surface that is coated by a metallic layer (e.g., permalloy). The diamagnetic system also includes a second substrate having at least one surface that is coated by graphene. The first and second substrates are immersed in an alkane (e.g., n-heptane). The diamagnetic system produces a diamagnetic response at room temperature in an applied magnetic field when the alkane is added to surround the permalloy and graphene.

### PRIORITY CLAIM

This application claims priority to and the benefit as a non-provisional application of U.S. Provisional Patent Application No. 62/992,391, filed Mar. 20, 2020, the entire content of which is hereby incorporated by reference and relied upon.

### STATEMENT REGARDING FEDERALLY SPONSORED RESEARCH OR DEVELOPMENT

This invention was made with government support under Grant/Contract Numbers N00014-16-2269, N00014-17-1-2972, N00014-18-1-2636, N00014-19-1-2265, and N00014-20-1-2442 awarded by the United States Office of Naval Research. The government has certain rights in the invention.

### BACKGROUND

Diamagnetism is a property of substance where magnetization M opposes an applied magnetic field H, (i.e., M=χH, where the susceptibility χ<0). Diamagnetism occurs as a result of microscopic electric currents of quantum nature and is a universal property of substances. However in many substances, diamagnetism is partially or completely masked off by paramagnetism or ferromagnetism—where χ>0. Typically, diamagnetism is a weak effect, so that |χ|<<1, (e.g., χ˜10⁻⁵). However, in superconductors, if an applied field is small enough, χ=−1. This phenomenon is called ideal diamagnetism. Currently, only superconductors reveal properties of ideal diamagnetism.

### SUMMARY

The system, method, and apparatus disclosed herein provide an ideal diamagnetism composition at room temperature. The disclosed system includes single-layer (or multi-layer) graphene on a substrate, which is immersed in n-heptane (a straight-chain alkane liquid). The system also includes a thin permalloy (nickel-iron magnetic alloy) foil that is placed in parallel to the graphene layer. The disclosed system potentially enables either room temperature superconductivity or represents a novel quantum effect in condensed matter physics. Room temperature superconductivity is more efficient compared to known superconductors, which require extremely low temperatures (and the corresponding cooling resources such as liquid nitrogen) to operate. The disclosed system may lead to applications for magnetic levitation. Additionally, the disclosed system may serve as a basis for superconducting quantum interference devices for the detection of extremely weak magnetic fields (e.g., can be used for applications such as land mine detection) and/or very fast computing electronics.

The disclosed system, method, and apparatus may exhibit the Meissner effect for superconductivity applications. Additionally or alternatively, the disclosed system, method, and apparatus may exhibit quantum effects for magnetic screening applications, levitation applications, and/or energy storage applications. Regardless of the end-use application, the example system, method, and apparatus have properties of diamagnetism at room temperature rather than at cryogenic temperatures, thereby enabling efficient and wide-spread commercial applicability.

In an example embodiment, a diamagnetism system includes a first substrate having a surface that is coated by a metallic layer and a second substrate having a surface that is coated by graphene. The first substrate may be separated from the second substrate by a distance between zero and some finite distance which enables diamagnetic properties. The first substrate may instead be a metallic foil such as permalloy, nickel, or cobalt. The second substrate may include a metallic layer (e.g., copper) to enable graphene to be grown thereon. Alternatively, the graphene may be grown on a temporary substrate and transferred to the second substrate.

The system also includes a coating of an alkane placed on the first substrate (or metallic foil) and the second substrate. In some embodiments, the alkane includes n-heptane, n-hexane, n-octane, etc. Instead of being coated, the substrates (or metallic foil) may be immersed into the alkane.

It is accordingly an advantage of the system, method, and apparatus to provide a composition that has properties of diamagnetism at room temperature.

Additional features and advantages are described in, and will be apparent from, the following Detailed Description and the Figures. The features and advantages described herein are not all-inclusive and, in particular, many additional features and advantages will be apparent to one of ordinary skill in the art in view of the figures and description. Also, any particular embodiment does not have to have all of the advantages listed herein and it is expressly contemplated to claim individual advantageous embodiments separately. Moreover, it should be noted that the language used in the specification has been selected principally for readability and instructional purposes, and not to limit the scope of the inventive subject matter.

### BRIEF DESCRIPTION OF THE FIGURES

FIG. 1 is a diagram of an apparatus that has ideal diamagnetic properties, according to an example embodiment of the present disclosure.

FIG. 2 shows a system that includes the diamagnetic apparatus of FIG. 1 in addition to a current source and a controller, according to an example embodiment of the present disclosure.

FIG. 3 is a diagram of the system of FIG. 2 with a Hall-sensor, according to an example embodiment of the present disclosure.

FIG. 4 is a diagram of the system of FIG. 2 where an alkane is coated on two substrates, according to an example embodiment of the present disclosure.

FIG. 5 shows a diagram of magnetic field distribution on a symmetry plane of an electromagnetic coil (vertical cylinder) and a permalloy disk, according to an example embodiment of the present disclosure.

FIG. 6 shows a diagram of an ideal diamagnetic response of alkane-wetted graphene in a presence of permalloy, according to an example embodiment of the present disclosure.

FIG. 7 shows a diagram of COMSOL Multiphysics finite element modeling of screening of a magnetic field of an electromagnetic coil by an ideal diamagnetic disk (relative permeability μ=0) with a non-ideal central part (where μ=1), according to an example embodiment of the present disclosure.

FIG. 8 shows a diagram of an enhancement of magnetic induction and subsequent flux freezing, according to an example embodiment of the present disclosure.

FIG. 9 shows a diagram of another example of an ideal diamagnetic response of alkane-wetted graphene in a presence of permalloy, according to an example embodiment of the present disclosure. When the diamagnetism is on and external magnetic field is off, the system keeps the frozen flux, which is opposite to the magnetic field that has been applied.

FIG. 10 is a diagram of a procedure to manufacture the diamagnetic apparatus of FIGS. 1 to 4, according to an example embodiment of the present disclosure.

### DETAILED DESCRIPTION

The system, method, and apparatus disclosed herein constitute an ideal diamagnetic composition at room temperature. The disclosed system includes single-layer (or multi-layer) graphene on a substrate, which is immersed in (or coated with) n-heptane (a straight-chain alkane liquid). The system also includes a thin permalloy (nickel-iron magnetic alloy) foil that is placed parallel to the graphene layer. The disclosed system potentially enables either room temperature superconductivity or represents a novel quantum effect in condensed matter physics. Room temperature superconductivity is more efficient compared to known superconductors, which require extremely low temperatures (and the corresponding cooling resources such as liquid nitrogen) to operate. The disclosed system may lead to applications for magnetic levitation. Additionally, the disclosed system may serve as a basis for superconducting quantum interference devices for the detection of extremely weak magnetic fields (e.g., can be used for applications such as land mine detection) and/or very fast computing electronics.

The disclosed system exhibits perfect screening of milligauss magnetic field (e.g., ideal diamagnetism) at room temperature. As disclosed herein, the system demonstrates ideal diamagnetism (no magnetic field inside the system) after injection of n-heptane, where the magnetic flux (B) drops down to a value of 0. The screening effect disappears if any of the disclosed components are absent, including n-heptane. This reproducible ideal diamagnetism may yield superconductivity at room temperatures and/or be indicative of a yet unknown effect in condensed matter physics.

While the disclosure refers to the system containing a thin permalloy foil, it should be appreciated that another substance (e.g. cobalt or nickel), that has very similar electrochemical potential as the permalloy, can also enable the system to achieve ideal diamagnetism. For example, the electrochemical potential of the permalloy foil is about −0.26 eV. Accordingly, the permalloy foil may be replaced by other metallic foils or metal layers with similar electrochemical potential, such as cobalt with an electrochemical potential of −0.28 eV or nickel with an electrochemical potential of −0.257 eV.

In some embodiments, the thin permalloy foil (or similar metallic foil) does not touch or have direct electrical contact with the graphene layer. Instead, n-heptane is provided between the permalloy foil and the graphene layer. In some examples, the foil and the graphene layer are immersed in n-heptane. In some examples, the n-heptane may be replaced by another alkane including n-hexane, n-octane, etc.

In an example embodiment, the disclosed system includes a silicon substrate instead of a metallic foil. In this embodiment, the silicon substrate has at least one surface that is coated by permalloy, cobalt, nickel, or similar metal via deposition. The disclosed system also includes a second substrate having at least one surface that is coated by a copper film. The silicon substrate surface is parallel to the second substrate. In some instances, a perfect (or near perfect) layer of graphene is grown on the copper film of the second substrate via chemical vapor deposition or a similar deposition method. In other instances, the copper film of the second substrate is omitted and the graphene is instead transferred to the second substrate. The first and second substrates are then placed into n-heptane. In some instances, both the first and second substrates are immersed in the n-heptane.

### Ideal Diamagnetism Embodiment

Graphene, since the time of its isolation, has proven to be a very fertile material for the exploration of novel features otherwise unattainable in solid-state objects. For example, graphite has long been recognized as an object with situation-dependent diamagnetic properties, exhibiting features that can be associated with superconductivity (even at room temperatures). The composite or apparatus disclosed herein includes single layer (or multiple layer) graphene that is wetted by n-heptane in the presence of at least one permalloy foil. The disclosed apparatus is a mixed solid-liquid system within the scope of condensed matter physics, rather than a traditional solid-state substance. The disclosed system has a diamagnetic response on the order of a weak, milligauss range magnetic field.

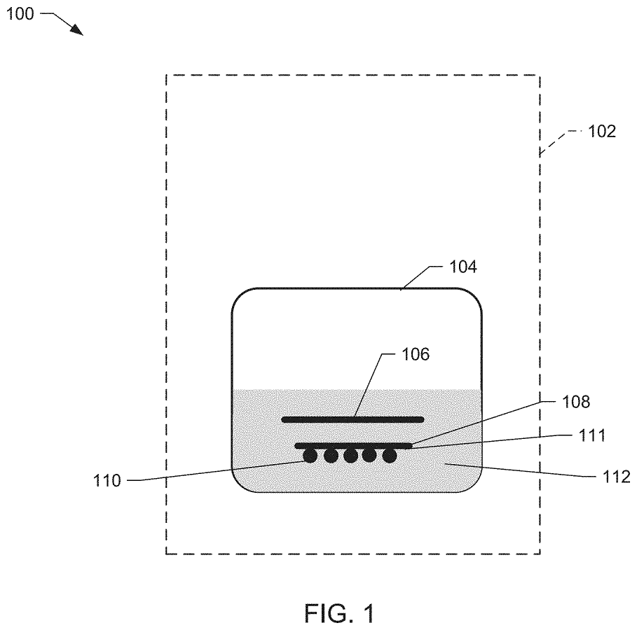

FIG. 1 is a diagram of an apparatus 100 that has ideal diamagnetic properties, according to an example embodiment of the present disclosure. The apparatus 100 includes an mu-shield 102 configured to compensate or reduce the effects of Earth's magnetic field down to 0.1 milligauss (“mG”). In some embodiments, the mu-shield 102 may be replaced by Helmholtz coils to provide compensation. Alternatively, the mu-shield 102 may be combined with Helmholtz coils to provide better compensation for an external noise field.

The example apparatus 100 also includes a housing or container 104. The example housing 104 may include glass or other inert material that does not react with the alkane and does not produce, attenuate, or otherwise affect a magnetic field. In some embodiments, the housing 104 may have an open top end. The housing 104 is configured to enclose a substrate 106 having at least one surface that is coated by a metallic layer or a freestanding metallic layer. The housing also encloses a second substrate 108 having at least one surface that is coated by graphene 110.

The first substrate 106 may include a silicon/silicon dioxide or quartz base. At least one surface of the first substrate 106 includes a metallic layer such as permalloy, cobalt, nickel, or another similar metal. The metallic layer may be grown on the substrate or be attached via a chemical or mechanical adhesive. Alternatively, the first substrate 106 may include a free standing metallic foil of permalloy, cobalt, nickel, or another similar metal. In these alternative embodiments, the first substrate 106 may comprise only the metallic foil.

The second substrate 108 may include silicon/silicon dioxide or quartz. In some embodiments, a layer of graphene 110 is grown on a temporary substrate and transferred to the second substrate 108. Alternatively, the second substrate 108 includes at least one surface that is coated with a metallic layer 111, such as copper. In this alternative embodiment, the graphene 110 is grown on the metallic layer 111. As shown in FIG. 1, the graphene 110 is provided on a surface of the second substrate 108 that is opposite of a surface that faces the first substrate 106. In instances where the first substrate 106 includes a single surface with a metallic layer, the layer is provided on a surface that faces the second substrate 108.

In the illustrated embodiment, the first substrate 106 is separated from the second substrate 108 by a distance between zero millimeters (or at least 1 micron) and a distance sufficient to cause diamagnetism between the first substrate 106 and the second substrate 108. Further, while the first substrate 106 is positioned above the second substrate 108, in other embodiments the second substrate 108 maybe positioned above the first substrate 106.

In some embodiments, a single substrate may be used. In this example, the substrate may include a silicon or quartz base (or another other dielectric base) with at least one metallic layer comprised of permalloy, nickel, or cobalt. An opposite side of the substrate includes graphene 110. If the graphene is grown on the substrate, the substrate may include a copper layer to enable the graphene growth.

The example housing 104 also includes an alkane 112 placed on both the first substrate 106 and the second substrate 108. In the illustrated example, the first substrate 106 and the second substrate 108 are immersed in the alkane 112. As discussed below, the addition of the alkane 112 reduces a magnetic permeability ,u of the apparatus 100 to a value of zero. In some embodiments, the alkane 112 may include n-heptane or a similar liquid such as n-hexane or n-octane.

It should be appreciated that the example housing 104 is configured to retain the substrates 106 and 108 and the alkane 112 in place. Movement of the substrates 106 and 108 relative to each other or relative to the alkane 112 may cause reduction or elimination of diamagnetic properties. The substrates 106 and 108 may be secured to a side of the housing 104. Alternatively, the substrates 106 and 108 may be connected to a bracket or other mechanical fastener within the housing 104.

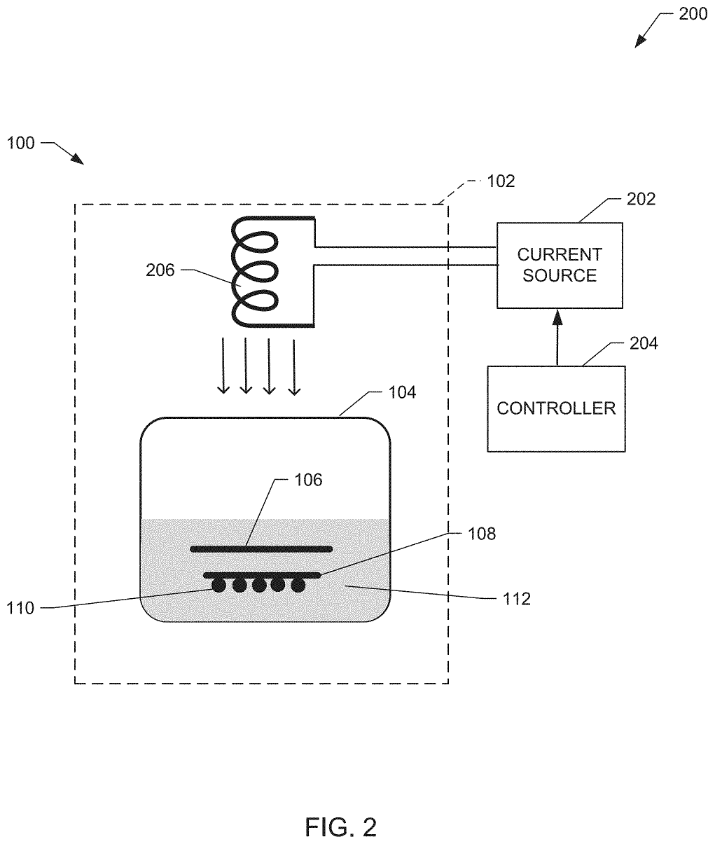

FIG. 2 shows a system 200 that includes the diamagnetic apparatus 100 of FIG. 1 in addition to a current source 202 and a controller 204, according to an example embodiment of the present disclosure. The example controller 204 includes a memory that stores one or more instructions. The controller 204 also includes a processor configured to execute the one or more instructions in the memory. Execution of the instructions in the memory by the processor cause the controller 204 to perform the operations discussed herein.

As shown in FIG. 2, the controller 204 is configured to transmit activation messages or signals to the current source 202. The messages and/or signals may indicate a magnitude of a current to apply to a wire coil 206. The messages and/or signals may also indicate a duration during which the current is to be applied.

The example current source 202 (e.g., a (Keithley-220®) is configured to use the messages and/or signals from the controller 204 to generate a corresponding current. The current source 202 is electrically connected to the wire coil 206 via a wire pair. The current source 202 provides a current to the wire coil 206 via the wire pair to generate a direct current (“DC”) magnetic field. An intensity of the DC magnetic field is defined by an amount of current applied to the wire coil 206 via the current source 202. In some instances, the wire coil 206 may be replaced by another component for creating the DC magnetic field. While FIG. 2 shows the wire coil 206 as being located outside of the housing 104, in other embodiments the wire coil 206 may be located inside of the housing 104.

In the applied DC magnetic field, the diamagnetic apparatus 100 exhibits diamagnetism as soon as n-heptane is added. As described above, the substrates 106 and 108 in addition to the alkane 112 are kept at room temperature. As such, the diamagnetic apparatus 100 exhibits diamagnetism properties at room temperature.

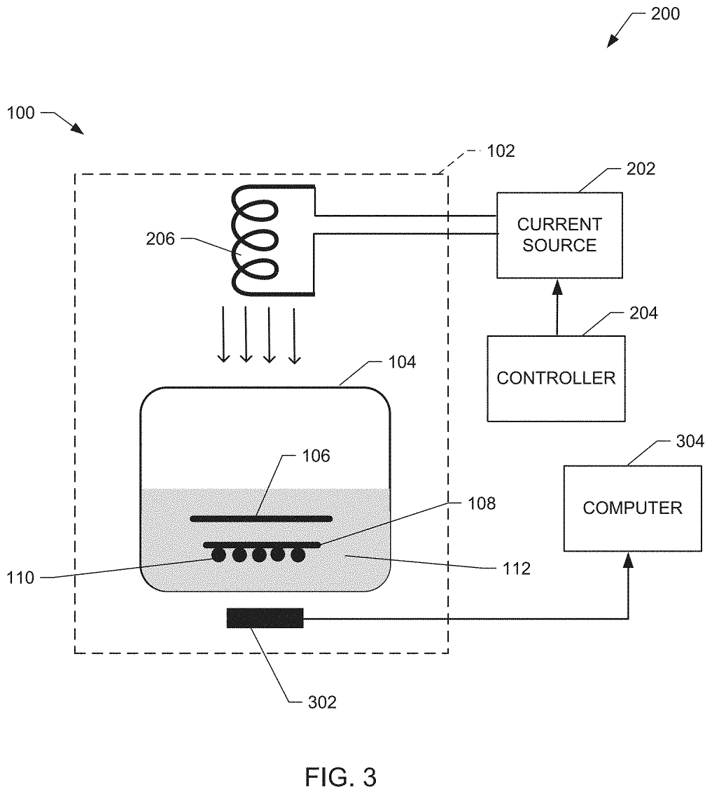

FIG. 3 is a diagram of the system 200 of FIG. 2 with a Hall-sensor 302, according to an example embodiment of the present disclosure. The Hall-sensor 302 may be combined with on-chip electronics such as the A1366LKTTN-10-T by Allegro Microsystems®, LLC. The Hall-sensor 302 is applied in a bridge measurement scheme to compensate its original a 2.5 volt output. An external voltage source, such as Keithley-230® may be used to compensate the output of the sensor 302. This enables values of magnetic field to be measured as deviations from zero by a nanovoltmeter, such as the Keithley-181®.

The example sensor 302 is communicatively coupled to a computer 304. The sensor 302 transmits data indicative of a measured magnetic field to the computer 304 for analysis and visualization. The computer 304 includes any processor, workstation, laptop, server, etc. for processing data indicative of a measured magnetic field. In the current embodiment, LabVIEW® software and a General Purpose Interface Bus (“GPIB”) connection were used.

The example sensor 302 may be used in an experimental setup discussed below to measure magnetic properties of the diamagnetic apparatus 100. Additionally or alternatively, the sensor 302 may be used in a commercial application to provide feedback control to the controller 304. For example, detection of a magnetic field (in the absence of DC current through the wire coil 206) may indicate that the apparatus 100 is not properly configured to provide diamagnetic properties or that an adjustment is needed to an applied DC magnetic field.

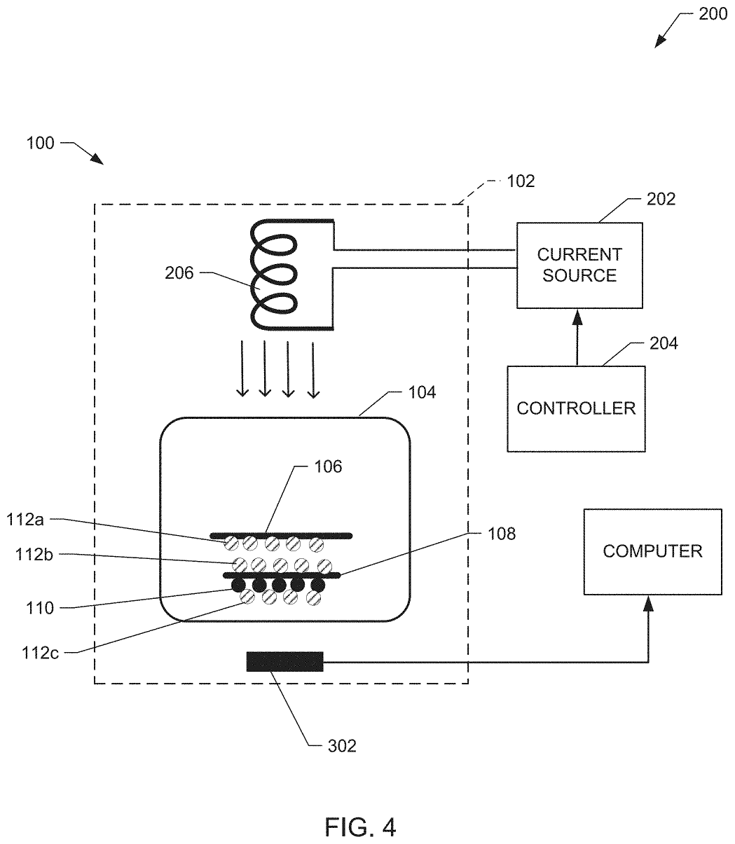

FIG. 4 is a diagram of the system 200 of FIG. 2 where the alkane 112 is coated on the first substrate 106 and the second substrate 108, according to an example embodiment of the present disclosure. In this example, the substrates 106 and 108 are not immersed in the alkane 112. Instead, the alkane 112 is placed on a surface of the first substrate 106 and an opposing surface of the second substrate 108. Alkane 112c is also placed on the graphene 110. The localized placement of the alkane 112 may provide the same effect as immersing the substrates 106 and 108 within the alkane 112, as shown in FIGS. 1 and 2. In some instances, the substrates 106 and/or 108 may include a glass or other non-conductive cap to retain the alkane 112 in place.

### Experimental Results

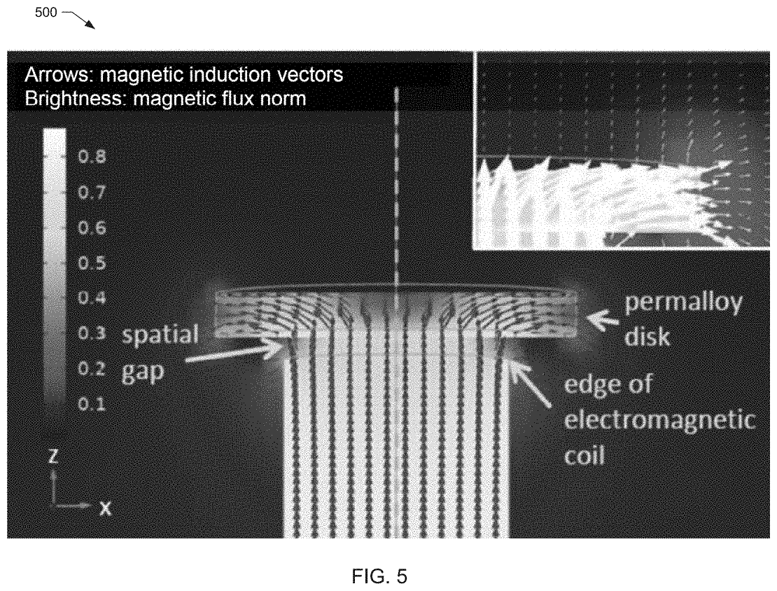

FIGS. 5 to 9 are diagrams illustrative of experiments to demonstrate the diamagnetic properties of the apparatus 100 of FIGS. 1 to 4. For these experiments, the system 200 with the sensor 302 of FIG. 3 was used. In this setup, the sensor sensitivity corresponds to 0.01 mG. During the measurements within the closed mu-shield 102, the n-heptane 112 was supplied by a fluorinated ethylene-propylene (“FEP”) pipe and syringe, and monitored by an internal camera. Later the FEP pipe was replaced by a stainless steel capillary to avoid interaction between n-heptane and FEP. Experiments were conducted in a glovebox with a controlled argon atmosphere. Some measurements were also made in an open-box arrangement, in ambient conditions, by inserting n-heptane via a pipette. To repeat measurements with the same graphene sample, two more pipes were used for removing liquids and supplying denaturized alcohol, which delivered a fast drying route for samples. A single layer graphene was used on Cu, SiO₂/Si, and Quartz substrates. The n-heptane was 99% grade. The permalloy of the first substrate 106 was used from different sources, with supermalloy composition (79% Ni, 16% Fe, and 5% Mo) at a thicknesses of 25 micron and 100 micron, and PC permalloy (77-78% Ni, 5% Mo, 4% Cu and Fe the remainder) at a thickness of 12 micron.

The housing 104 included a Pyrex® glass beaker. Glassblowing work was done to make the bottom of the housing 104 flat or sagging a bit for easier access of liquid 112 to the central part of the graphene layer 110.

In the initial experiments, the permalloy foil of the first substrate 106 was used with the intention of reducing the amplitude of the external magnetic flux at the location of the graphene 110. There is also a question of magnetic field direction. Modeling of the magnetic field revealed that in the disclosed configuration where the graphene 110 and the permalloy of the first substrate 106 are separated by the second substrate 108, the normal component of the field is prevailing (see graph 500 of FIG. 5). Additionally in this modeling, the reduction of the field amplitude immediately beyond the permalloy as a function of its thickness was in quantitative agreement with the experimentally measured values.

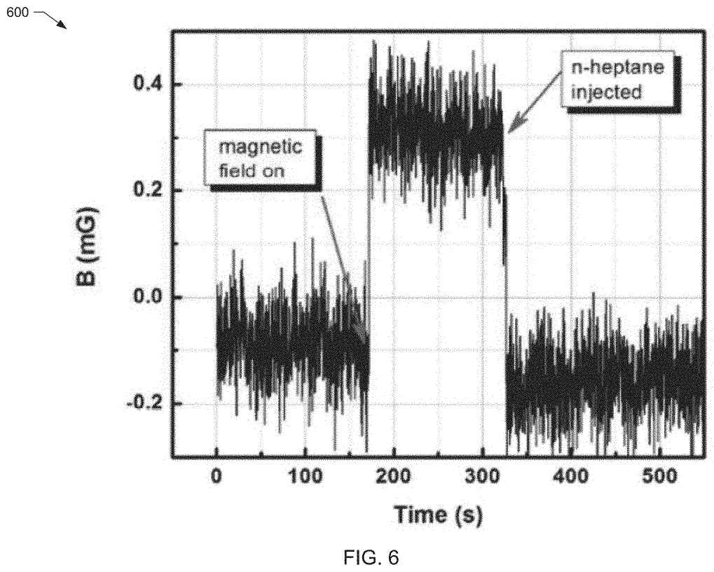

FIG. 6 shows a graph 600 of an ideal diamagnetic response of the apparatus 100 of FIGS. 1 to 4, according to an example embodiment of the present disclosure. As shown in this figure (which is typical for the multitude of measured samples), after the pristine graphene 110 is placed in the housing 104 with the graphene facing the Hall sensor 302 and the permalloy foil of the substrate 106 placed on top, the magnetic field is switched on. At this point, the sensor 302 detects a non-zero magnetic induction B that is centered around 0.1 mG. As soon as the n-heptane 112 is added or injected, the detected magnetic induction B=μH falls to zero, which indicates that the magnetic permeability μ is zero, so that the magnetic susceptibility χ of the system 200 is χ=−1. This means that the level of screening is ideal. It is about 3000 times stronger than that of highly-oriented pyrolytic graphite (“HOPG”), which has the highest known value of χ at room-temperatures, and which revealed no screening signature when graphene was replaced by HOPG in the apparatus 100.

It should be appreciated that this reported effect shown in FIG. 6 does not depend on the polarity of the magnetic field. For instance, zeroing of the readouts of the Hall-sensor 302 also occur at oppositely oriented magnetic field. More importantly, the screening does not occur when the permalloy of the first substrate 106 is absent. Numerous attempts to obtain the diamagnetic properties in the absence of the permalloy failed. The reduction of the field caused by permalloy alone in these experiments could be mimicked by reducing the current in the wire coil 206, so that the amplitude of the field detected by the sensor 302 prior to applying n-heptane 112 was the same as with the permalloy of the first substrate 106. Also, the direction of the magnetic field still is normal to the graphene 110, as shown in the modeling of FIG. 5. Absence of the screening effects related to diamagnetism points to some non-magnetic influence of the permalloy of the first substrate 106.

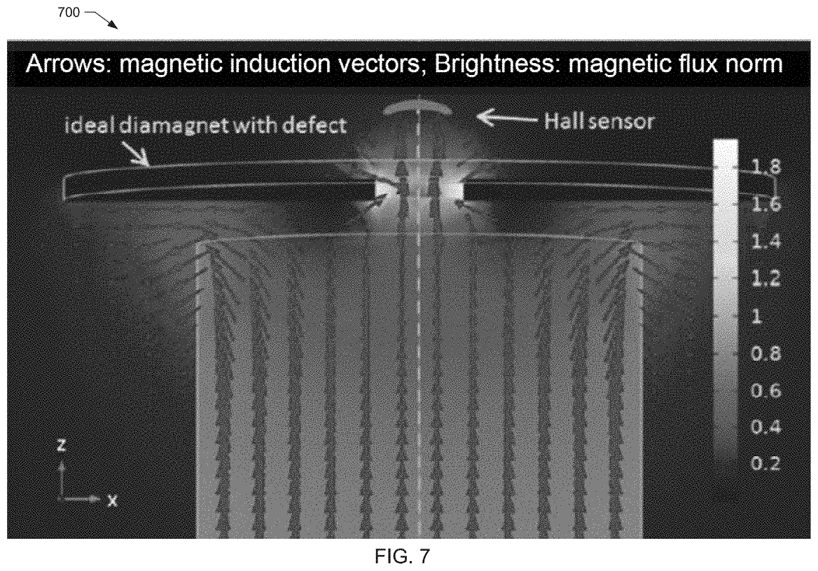

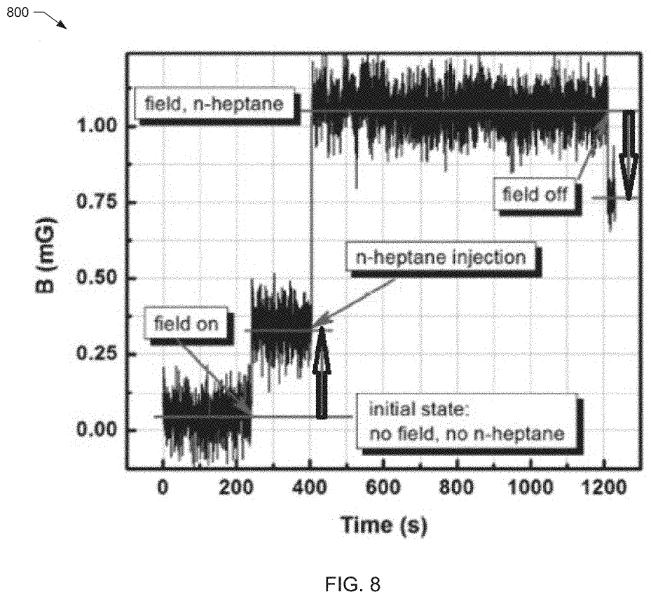

To understand the effect of graphene layer 112 inhomogeneity, additional modeling was performed on an ideal diamagnet (relative permeability μ=0) with a spatial defect (where μ˜1). The ideal diamagnet with spatial defects can amplify locally the magnetic flux. The results are shown in FIG. 7. Note that there is a factor of more than three amplification near the internal edge of the ideal diamagnet, thereby resulting in an enhanced field value at the Hall sensor 302. Thus, if the detector 302 is located near this imperfection area (as shown in FIG. 7) it will indicate an increase of magnetic flux norm. This, at first glance, was registered on some of the SiO2/Si-substrate graphene films 112 after the transition (shown in FIG. 8).

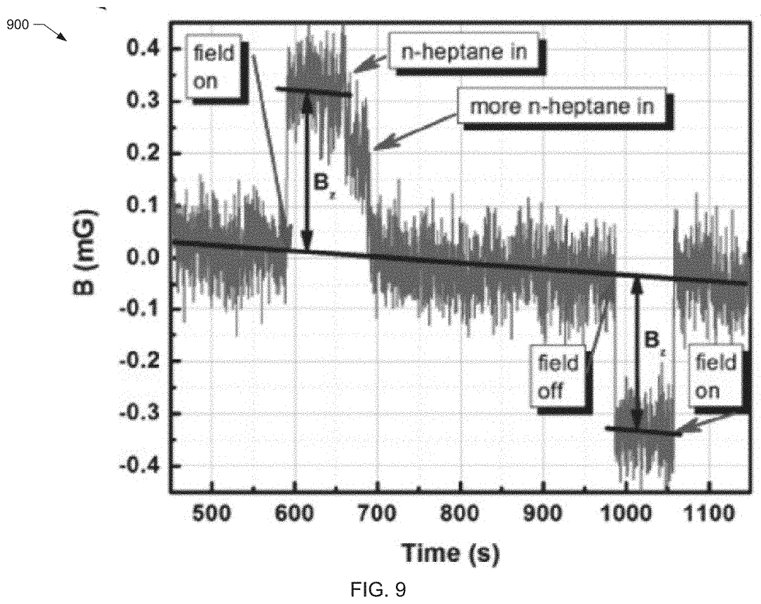

However, the situation shown in FIG. 7 may be more complex. Indeed, in the above-discussed case considered during modeling, as soon as the magnetic field is off, the sensor 302 should show an induction value of zero. However, in experiment, as follows from FIG. 8, after the applied field is turned off, the sensor 302 indicates the remnant value equal in magnitude to the jump that occurred when the n-heptane 112 was injected at the field-on state. It can be concluded that the concentrated magnetic flux stays “frozen” around the spatial defect after the H-field is off. A different scenario of “freezing” is shown in FIG. 9 for the case with no spatial defect. As soon as the ideal diamagnetic state (μ=0) is set up, the magnetic induction B=μH is zero. This shows that the system 200 developed its own magnetic moment M, which compensates the field H: M=−H. When the applied H-field reduces to zero, the magnetic moment M remains “frozen”.

These experimental observations confirm and further extend the initial results on magnetic response. Until now, perfect screening (μ=0) was attributed only to superconductivity. Either the disclosed apparatus 100 is a superconductor (with extremely small values of the first critical field H_{c1}), or possibly the apparatus 100 comprises an ideal diamagnetic substance of unknown physical origin. One of the most interesting aspects of this research is the role of the permalloy of the first substrate 106. The thickness of permalloy does not have a significant effect on the results. Instead, the thickness only reduces the value of B-field. Working with thinner foil is easier, since it almost does not change the field value. One can think of permalloy as affecting the results not magnetically, but rather electrochemically.

As provided above, the disclosed apparatus 100 reproducibly provides observations regarding the screening of milligauss-range magnetic fields by a condensed matter system consisting of pristine graphene, n-heptane and permalloy. The screening is ideal such that it corresponds to χ=−1, i.e., χ=−1/(4π) in Gaussian units. This indicates a presence of either a room temperature, ambient pressure superconductor or a yet unknown type of ideal diamagnetic complex material.

### Example of a Diamagnet Manufacturing Procedure

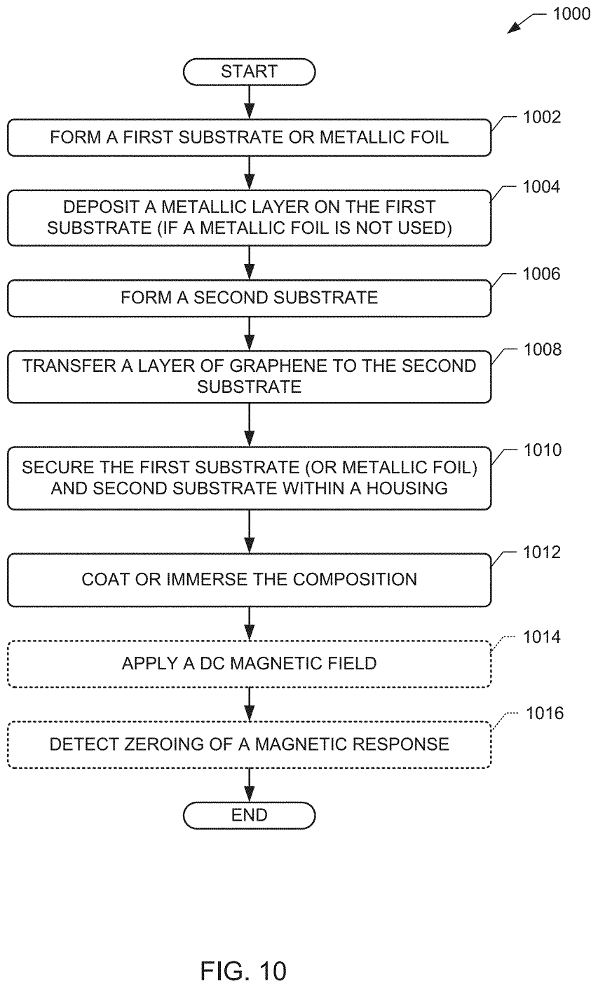

FIG. 10 is a diagram of an example procedure 1000 to manufacture the diamagnetic apparatus 100 of FIGS. 1 to 4, according to an embodiment of the present disclosure. Although the procedure 100 is described with reference to the flow diagram illustrated in FIG. 10, it should be appreciated that many other methods of performing the steps associated with the procedure 1000 may be used. For example, the order of many of the blocks may be changed, certain blocks may be combined with other blocks, and many of the blocks described may be optional. In an embodiment, the number of blocks may be changed. For instance, steps related to creation of the first and second substrates 106 and 108 may be combined if a single substrate is used.

The example procedure 1000 begins when a first substrate 106 is formed (block 1002). The first substrate 106 may be formed from silicon/silicon dioxide or quartz. Alternatively, the first substrate 106 comprises a metallic foil such as permalloy, cobalt, nickel, or another similar metal.

If the first substrate 106 is a dielectric, a metallic layer is coated on at least one surface of the first substrate 106 (block 1004). The metallic layer may include at least one of permalloy, cobalt, nickel, or another similar metal and be deposited via deposition or sputtering. The permalloy may have a composition of 79% Ni, 16% Fe, and 5% Mo at thicknesses between 1 micron to 100 micron. Alternatively, the permalloy may have a composition of 77-78% Ni, 5% Mo, 4% Cu, and the remainder Fe at thickness of about 12 micron. If the first substrate is a foil, this step is omitted.

The example procedure 1000 continues by forming a second substrate 108 (block 1006). The second substrate 108 may include silicon/silicon dioxide or quartz. A layer of graphene 110 may be grown on a temporary substrate and transferred to the second substrate (block 1008). The graphene 110 may be grown via chemical vapor deposition or a similar deposition method. Alternatively, a metallic layer (e.g., a copper layer) may be deposited on at least one surface of the second substrate 108. The graphene 110 may be grown on the metallic layer of the second substrate 108 instead of being transferred.

The first and second substrates 106 and 108 are then connected or otherwise placed into a housing 104 (block 1010). The substrates 106 and 108 may be parallel with each other and separated by a distance of at least 1 micron. An alkane 112 is then placed on the first and second substrates 106 and 108 (e.g., a composition) (block 1012). Alternatively, the alkane 112 is added to the housing 104 to immerse the first and second substrates 106 and 108. The example procedure 1000 concludes when the housing 104 is secured. In some embodiments, the housing 104 may be installed into a commercial application. Additionally, a DC magnetic field is applied to induce the diamagnetic property with the addition of n-heptane (block 1014). Further, a sensor 302 may detect zeroing of a magnetic response that is indicative of diamagnetism (block 1016).

### CONCLUSION

It should be understood that various changes and modifications to the presently preferred embodiments described herein will be apparent to those skilled in the art. Such changes and modifications can be made without departing from the spirit and scope of the present subject matter and without diminishing its intended advantages. It is therefore intended that such changes and modifications be covered by the appended claims.

The invention is claimed as follows:

1. A diamagnetism system comprising:
a metallic foil or a first substrate having at least one surface that is coated by a metallic layer;
a second substrate having at least one surface that is coated by graphene; and
a coating of an alkane placed on the second substrate and the metallic foil or the first substrate.

2. The system of claim 1, wherein the metallic layer includes at least one of a coating or a foil of permalloy, nickel, or cobalt.

3. The system of claim 1, wherein the second substrate includes a second metallic layer upon which the graphene is deposited.

4. The system of claim 3, wherein the second metallic layer includes copper.

5. The system of claim 3, wherein the graphene is grown on the second metallic layer via chemical vapor deposition.

6. The system of claim 1, wherein the graphene is transferred to the second substrate.

7. The system of claim 1, wherein the metallic foil or the first substrate is parallel to the second substrate.

8. The system of claim 1, wherein at least one of the first substrate or the second substrate is a silicon/silicon dioxide substrate or a quartz substrate.

9. The system of claim 1, wherein the alkane corresponds to n-heptane, n-hexane, or n-octane.

10. The system of claim 1, wherein the second substrate and the metallic foil or the first substrate or are immersed into the alkane.

11. The system of claim 1, wherein the metallic foil or the first substrate is integrally formed with the second substrate.

12. The system of claim 1, wherein the second substrate is separated from the first substrate or the metallic foil by a distance of at least 1 micron.

13. The system of claim 1, wherein the second substrate is in contact with the first substrate or the metallic foil.

14. A diamagnetism apparatus comprising:
a substrate having at least a single layer of graphene;
a metallic foil that is parallel to the substrate; and
an alkane that wets the graphene and the metallic foil.

15. The apparatus of claim 14, wherein the alkane includes n-heptane and the metallic foil includes at least one of permalloy, nickel, or cobalt.

16. The apparatus of claim 14, wherein the graphene and the metallic foil are immersed in the alkane.

17. A method of manufacturing a diamagnetism apparatus, the method comprising:
forming a first substrate or a metallic foil;
if a first substrate is used, depositing a first metallic layer on at least one surface of the first substrate;
forming a second substrate;
transferring graphene to a surface of the second substrate; and
at least one of coating or immersing the first substrate or the metallic foil and second substrate with an alkane.

18. The method of claim 17, wherein the first substrate includes at least one of silicon/silicon dioxide or quartz, and
wherein the first metallic layer includes at least one of permalloy, nickel, or cobalt.

19. The method of claim 18, wherein the permalloy has a composition of at least one of:
79% Ni, 16% Fe, and 5% Mo at thicknesses between 1 micron to 100 micron; or
77-78% Ni, 5% Mo, 4% Cu, and the remainder Fe at thickness of about 12 micron.

20. The method of claim 17, wherein the second substrate includes at least one of silicon/silicon dioxide or quartz, and
wherein the second metallic layer includes copper.

21. The method of claim 17, further comprising:
connecting the first and second substrates in parallel within a housing; and
applying a DC magnetic field via a wire coil.

22. The method of claim 17, wherein the alkane includes 99% grade n-heptane.
